(19) United States
(12) Patent Application Publication
(10) Pub. No.: US 2025/0192538 A1
(43) Pub. Date: Jun. 12, 2025

(54) SWITCHING A SEMICONDUCTOR SWITCH BY MEANS OF A MEASURING CIRCUIT AND A CONTROL DEVICE

(71) Applicant: dSPACE GmbH, Paderborn (DE)

(72) Inventor: Paul GRUBER, Paderborn (DE)

(73) Assignee: dSPACE GmbH, Paderborn (DE)

(21) Appl. No.: 18/974,672

(22) Filed: Dec. 9, 2024

(30) Foreign Application Priority Data
Dec. 8, 2023 (DE) 10 2023 134 442.0

(51) Int. Cl. H02H 3/08; H02H 1/00

(52) U.S. Cl. CPC H02H 3/08; H02H 1/0007

(57) ABSTRACT

An arrangement comprising a semiconductor switch, a measuring circuit, and a control device are provided. The semiconductor switch has a load path input and a load path output as well as a switching signal input. The measuring circuit has a load path input, a shunt, a load path output routed to the load path input of the semiconductor switch. A voltage tap and an overload detector with an overload signal output, which is routed to the control device. The overload detector detects the presence of an overload on a load path and issues an overload signal to the control device in the event of an overload. The control device is connected to the switching signal input of the semiconductor switch. The control device feeds a switching signal to the semiconductor switch for opening the semiconductor switch if the control device has received an overload signal.

This nonprovisional application claims priority under 35 U.S.C. § 119(a) to German Patent Application No. 10 2023 134 442.0, which was filed in Germany on Dec. 8, 2023, and which is herein incorporated by reference.

### BACKGROUND OF THE INVENTION

### Field of the Invention

The invention relates to an arrangement, comprising a semiconductor switch, a measuring circuit, and a control device as well as a method for switching a semiconductor switch by means of a measuring circuit and a control device.

### Description of the Background Art

So-called HIL simulators are known from the state of the art, which are used in particular for testing electronic control units (“HIL” derived from “Hardware in the Loop”). HIL simulators each comprise at least one computer unit, wherein the computer unit or computer units have the task of executing models that at least partially simulate an environment of an electronic device or a more complex technical system.

HIL simulators thus enable a test procedure in which an embedded system, in particular an electronic control unit (ECU) or a mechatronic module, is connected via its inputs and outputs to an adapted counterpart, namely the HIL simulator, which is used to simulate the real environment of the embedded system. In the context of an HIL simulation, the embedded system is also referred to as a device under test (DUT). Thus, during the test of the embedded system, at least part of the input signals for the embedded system are provided by the HIL simulator and at least part of the output signals of the embedded system are sent to the HIL simulator.

For example, an environment model running on an HIL simulator can be used to simulate the temporal behavior of the environment of the system under test. If, for example, an HIL simulator is to test an embedded system, in particular an ECU, then the HIL simulator is designed as at least a partial replica of the real environment of the ECU. In this case, the HIL simulator can communicate with the ECU via its inputs and outputs, or its bidirectional communication channels equipped with a bus or network interface and thus act as an adapted counterpart of the ECU.

The HIL simulation is always only a simplification of reality and therefore cannot replace the test on the real system. If there are too many discrepancies between an HIL test and reality, the underlying models in the simulation are oversimplified. Then, the simulation models will have to be further developed.

An essential part of HIL testing is fault simulations to test the response of the ECU to fault situations. In order to simulate cable breaks or similar faults, additional plug-in cards for HIL systems or external devices that can also be connected to the HIL systems, e.g., via bus or network interfaces, are generally available, so-called Failure Insertion Units (FIUs), hereinafter also referred to as Failure Injection Units. They include circuits with remotely and automatically controllable switches for simulating, for example, cable breaks, short circuits, and/or so-called contact bouncing (bouncing in the context of the above-mentioned faults, “loose contact”), which can lead to unwanted modulation. FIUs are available for both sensors and actuators, wherein they are also combined with load devices for actuators. In particular, the FIUs can be used to generate simulation signals that represent non-normal, i.e., fault-prone operating states. This means that an electrical component can be tested not only with regard to regular operation, but also with regard to various fault and/or malfunction states.

DE 10 2009 048 981 A1, which corresponds to US 2011/0087477, which is incorporated herein by reference, describes an FIU in the form of a device for testing an electronic component with a simulation device for generating a simulation signal, a test device for connecting the electronic component, two connection devices and a selection device for selecting the connection device, wherein the simulation device and the test device can be connected electrically conductively to one of the connection devices by means of the selection device and the individual connecting devices differ from each other with regard to at least one electrical property. The simulation device is designed in such a way that simulation signals can be generated for different operating states of the electronic component and, in particular, simulation signals for faulty operating states of the electrical component can be provided by means of an FIU.

In conventional FIUs, the signal lines are typically connected to the ground potential or positive potential line, i.e., with 0 V or up to +60 V, so that an object under test can be subjected to a corresponding voltage. For example, semiconductor switches, such as MOSFET switches, can be provided for this voltage application, but they should be protected in the event of potential overloads. The load path can also be interrupted to simulate a cable break.

### SUMMARY OF THE INVENTION

It is therefore an object of the invention to provide a simple and efficient option for overload protection of a semiconductor switch.

According to an example of the invention, an arrangement with a semiconductor switch, a measuring circuit and a control device is thus provided.

The semiconductor switch can have a load path input and a load path output for connection to a load path and a switching signal input for receiving a switching signal for opening or closing the semiconductor switch, wherein the load path input and the load path output are connected to each other when the semiconductor switch is closed and separated from each other when the semiconductor switch is open.

The measuring circuit can have a load path input with which the measuring circuits can be connected to the load path, a shunt downstream of the load path input, a load path output downstream of the shunt that is routed to the load path input of the semiconductor switch, a voltage tap for the voltage dropping across the shunt and an overload detector downstream of the voltage tap with an overload signal output, which is routed to the control device.

The overload detector can be designed to detect the presence of an overload on the load path and, in the event of an overload, to output an overload signal to the control device via the overload signal output.

The control device can be connected to the switching signal input of the semiconductor switch via a switching signal line.

The control device can be designed to supply the semiconductor switch with a switching signal for opening the semiconductor switch via the switching signal line if the control device has received an overload signal from the overload detector via the overload signal output.

The control device can be set up to supply the semiconductor switch with a switching signal for closing the semiconductor switch via the switching signal line after the overload signal has disappeared, provided that the overload has amounted to a maximum of a predetermined maximum overload, and in a case where the overload has exceeded the predetermined maximum overload, to not generate a switching signal for closing the semiconductor switch even after the overload signal has disappeared.

This provides a simple and efficient option for overload protection of the semiconductor switch, which is non-destructive, has a high switching capacity and basically enables restart without user intervention. According to the invention, however, such a restart only occurs if the overload has amounted to a maximum of a predetermined maximum overload. If the overload has exceeded the predetermined maximum overload, no further switching signal is generated for closing the semiconductor switch even after the overload signal has disappeared. Rather, user intervention is then required, under which the functionality of the arrangement can be checked for further use, or the arrangement can be replaced.

The time control of the switching signal is possible in diverse ways. However, according to an example of the invention, the control device can be set up to supply the switching signal to the semiconductor switch via the switching signal line for closing the semiconductor switch at a time that is delayed after the time of the removal of the overload by such a delay period as is a function of the overload and increases with it. According to this embodiment, the greater the recorded overload, the longer the restart is delayed. This embodiment takes into account that in the event of a severe overload, the arrangement can be overstressed by attempts to restart too quickly.

In the context of the timing of the switching signal described above, it is particularly preferable that the overload detector can have an integrator, which is set up to integrate the current on the load path into a load, and, in the event that the load has reached a predetermined first overload threshold, to output an overload signal to the control device via the overload signal output until the load has fallen below a second overload threshold. In addition, the control device is set up to measure the duration of receiving the overload signal and the control device is designed to generate a switching signal for closing the semiconductor switch, provided that the duration of receiving the overload signal has not exceeded a predetermined maximum duration, and in a case where the duration of receiving the overload signal has exceeded the predetermined maximum duration, to no longer generate a switching signal for closing the semiconductor switch, and wherein the control device is designed to supply the switching signal to the semiconductor switch via the switching signal line for closing the semiconductor switch at a time when a delay period has elapsed after the overload signal has disappeared, which delay period is a function of the duration of receiving the overload signal and increases with it. It is particularly preferable that the second overload threshold is lower than the first overload threshold and is determined from the first overload threshold minus a hysteresis interval.

The design of the arrangement described above is further developed in that the control device is designed to repeatedly supply the semiconductor switch with a switching signal for closing the semiconductor switch via the switching signal line in the event the semiconductor switch fails to close, with a time interval between the successive switching signals, which is a function of how long it takes to receive the overload signal and increases with it. A restart is therefore attempted several times, with intervals between the different restart attempts, which are all the greater the longer it takes to receive the overload signal.

Such restart attempts can be made as often as desired. However, according to an example of the invention, the control device can be designed to repeatedly supply the semiconductor switch with a switching signal for closing the semiconductor switch via the switching signal line in the event the semiconductor switch fails to close, but at most a number of times that is a function of the duration of receiving of the overload signal and decreases with it. In this context, it is particularly preferable that, in the event of an overload below a third overload threshold that is less than the maximum overload, at least 20 to a maximum of 40 restart attempts are made at intervals of 500 ms to 800 ms and then further attempts, preferably any number of attempts, with time intervals between 2 s and 10 s.

The overload detector, as an integrator, can have a capacitor. Such a capacitor also acts as a filter. Preferably, in addition to the capacitor, a nonlinear circuit part is provided, which is configured to approximate the I2t behavior to a real fuse.

The arrangement according to the invention does not require additional amplifiers. However, according to a further example of the invention, a preamplifier with a signal rectifier can be arranged upstream of the integrator. A threshold comparator and subsequently a signal isolator can be arranged downstream of the integrator.

The control device has an FPGA or a microcontroller. An FPGA (Field Programmable Gate Array) is an integrated circuit designed to be configured by the user once manufactured. Preferably, the semiconductor switch is a MOSFET switch designed to shut down a current direction. The semiconductor switch can be a series connection of two MOSFET switches, wherein the so-called body diodes of the two MOSFET switches are arranged along the series circuit with opposite blocking directions, so that by means of the semiconductor switch, a current flow through the load path can preferably be safely controlled in both technical current directions and, in particular, safely interrupted.

According to the invention, a method for switching a semiconductor switch by means of a measuring circuit and a control device is also provided, wherein the measuring circuit comprises: a load path input with which it is connected to a load path; a shunt connected in series downstream of the load path input; a load path output connected in series downstream of the shunt, which is routed to the semiconductor switch; a voltage tap for the voltage dropping across the shunt; and an overload detector connected in series downstream of the voltage tap with an overload signal output, which is routed to the control device, with the following method steps: detecting the presence of an overload on the load path by means of the overload detector and, in the event of an overload, issuing an overload signal to the control device via the overload signal output; feeding a switching signal for opening the semiconductor switch from the control device to the semiconductor switch via the switching signal line if the control device has received an overload signal from the overload detector via the overload signal output; and feeding a switching signal for closing the semiconductor switch from the control device to the semiconductor switch via the switching signal line after the overload signal has disappeared, provided that the overload has amounted to a maximum of a predetermined maximum overload.

Thus, in the context of the invention, in a case where the overload has exceeded the predetermined maximum overload, no switching signal is generated for closing the semiconductor switch even after the overload signal has disappeared.

According to an example, if the control device has received an overload signal from the overload detector via the overload signal output, the switching signal for opening the semiconductor switch can be fed from the control device to the semiconductor switch via the switching signal line, with an additional constant delay in the time range of 20 μs to 40 μs, for example with a constant delay of 30 μs. During this time, an integrator can ramp even further up, so that the extent of the overload can be measured even more precisely.

Furthermore, preferably after the overload signal has disappeared, an additional waiting time is generated before the semiconductor switch is closed, even with only a slight overload, in the time range of 0.5 to 1 s. In the event of a particularly high detected overload, no restart attempt is made.

The switching signal for closing the semiconductor switch can be fed to the semiconductor switch via the switching signal line at a time that, after the time the overload ceases, is delayed by a delay period that is a function of the overload and increases with it.

Furthermore, it is also preferable that the method according to the invention can be further developed with the following steps: integrating the current on the load path to a load by means of an integrator of the overload detector, and, in the event that the load has reached a predetermined first overload threshold, outputting an overload signal via the overload signal output to the control device until the load has fallen below a second overload threshold, measuring the time it takes to receive the overload signal by means of the control device, generating a switching signal for closing the semiconductor switch by means of the control device, provided that the time it takes to receive the overload signal has not exceeded a predetermined maximum duration, and feeding of the switching signal for closing the semiconductor switch from the control device to the semiconductor switch via the switching signal line at a time when a delay period has elapsed after the overload signal has disappeared, which is a function of the time it takes to receive the overload signal and increases with it.

In a case where the time to receive the overload signal has exceeded the predetermined maximum duration, a switching signal is no longer generated for closing the semiconductor switch.

The switching signal for closing the semiconductor switch can be repeatedly fed from the control device to the semiconductor switch via the switching signal line if the semiconductor switch fails to close, with a time interval between the successive switching signals that is a function of the time it takes to receive the overload signal and increases it.

A switching signal for closing the semiconductor switch can be repeatedly supplied from the control device to the semiconductor switch via the switching signal line if the semiconductor switch fails to close, but at most in a number that is a function of the time it takes to receive the overload signal and falls with it.

The arrangement and method described above can be provided for very different uses. However, according to a preferred further development of the invention, the arrangement and method are used for a Failure Insertion Unit. Failure Insertion Units (FIUs), also known as Failure Injection Units, can be connected to HIL systems, and are used to simulate cable breaks or similar faults. Such FIUs include circuits with remotely and automatically controllable switches to simulate, for example, cable breaks, short circuits, and/or so-called contact bouncing, which can lead to unwanted modulation. FIUs are available for both sensors and actuators, wherein when used with actuators they are also combined with load devices. In particular, the FIUs can be used to generate simulation signals that represent non-normal, i.e., fault-prone operating states. This means that an electrical component can be tested not only with regard to regular operation, but also with regard to various fault and/or malfunction states.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 shows a block diagram of an arrangement comprising a semiconductor switch, a measuring circuit, and a control device according to a preferred embodiment of the invention;

FIG. 2 shows a block diagram with details of the measuring circuit from FIG. 1;

FIG. 3 shows the time behavior of a method according to the preferred embodiment at a lower overload; and

FIG. 4 shows the time behavior of a method according to the preferred embodiment at a higher overload.

### DETAILED DESCRIPTION

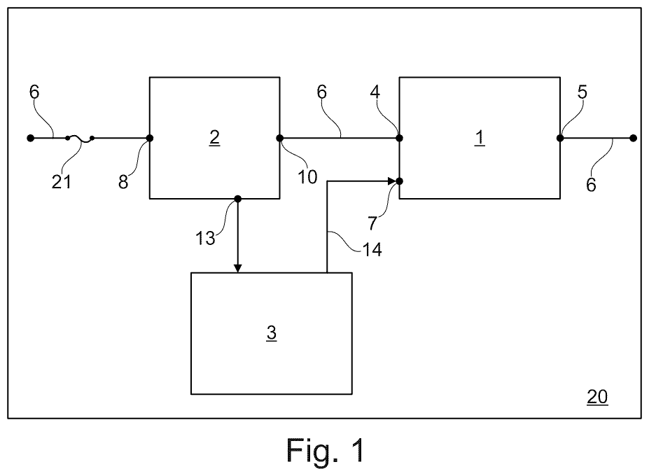

FIG. 1 shows a block diagram of an arrangement comprising a semiconductor switch 1, a measuring circuit 2 and a control device 3 in the form of an FPGA according to a preferred embodiment of the invention. This arrangement is part of a Failure Insertion Unit 20, which can be connected to HIL systems and is used to simulate cable breaks or similar faults for an HIL simulation. For this purpose, the Failure Insertion Unit 20 has a plurality of load paths, of which one load path 6 is shown here as an example, which is provided with a fuse 21 upstream of the measuring circuit 1. The load path 6 is routed through the measuring circuit 2 to the semiconductor switch 1. The semiconductor switch 1 is a MOSFET switch and has a load path input 4 and a load path output 5 for connection to the load path 6 as well as a switching signal input 7 for receiving a switching signal for opening or closing the semiconductor switch 1, wherein the load path input 4 and the load path output 5 are connected to each other in the closed state of the semiconductor switch 1 and separated from each other in the open state of the semiconductor switch 1.

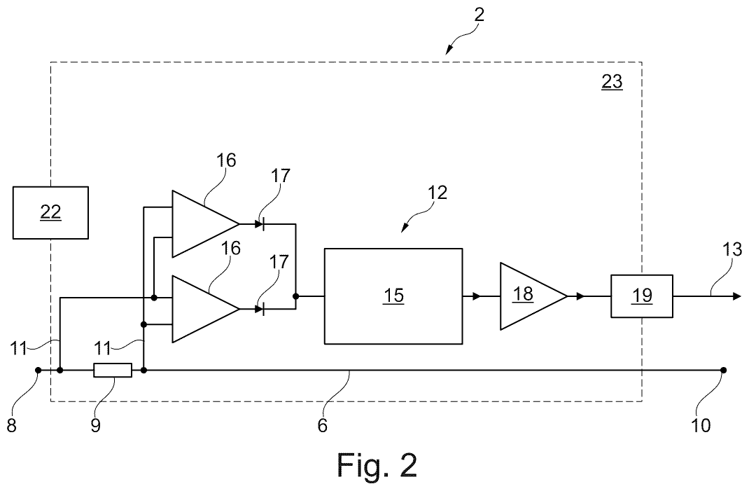

In the present case, the measuring circuit 2 serves to detect an overload on the load path 6 and, as can be seen in particular from FIG. 2, has a load path input 8 with which the measuring circuit 2 can be connected to the load path 6, a shunt 9 connected in series downstream of the load path input 8, a load path output 10 connected in series downstream of the shunt 9 which is routed to the load path input 4 of the semiconductor switch 1, a voltage tap 11 for the voltage dropping across the shunt 9 and an overload detector 12 connected in series downstream of the voltage tap 11 with an overload signal output 13, which is routed to the control device 3. The overload detector 12 has a capacitor as integrator 15. Upstream of the integrator 15 is a preamplifier 16 with a signal rectifier 17. The preamplifier 16 preferably includes two op-amps, of which a first op-amp is designed with positive gain and a second op-amp with negative gain. In addition, downstream of the integrator 15 are a threshold comparator 18 and subsequently a signal isolator 19. FIG. 2 shows the potential-free part 23 of the measuring circuit 2, for which the measuring circuit 2 is provided with an isolated supply 22.

The decisive factor is that the overload detector 12 is set up to detect the presence of an overload on the load path 6 and, in the event of an overload, to output an overload signal to the control device 3 via the overload signal output 13. The control device can then act on the semiconductor switch 1. For this purpose, the control device 3 is connected to the switching signal input 7 of the semiconductor switch 1 via a switching signal line 14 and is set up to supply a switching signal to the semiconductor switch 1 via the switching signal line 14 for opening the semiconductor switch 14 if the control device 3 has received an overload signal from the overload detector 12 via the overload signal output 13. After the end of the overload, and thus after the overload signal has disappeared, the control device 3 again feeds a switching signal to the semiconductor switch 1 for closing the semiconductor switch 1 via the switching signal line 14, but only if the overload has amounted to a maximum of a predetermined maximum overload. However, if the overload has exceeded the predetermined maximum overload, no switching signal is generated for closing the semiconductor switch 1 even after the overload signal has disappeared. In this case, a user must intervene to check the arrangement and, if necessary, to put it back into operation manually.

In addition, the control device 3 is set up in such a way that the switching signal for closing the semiconductor switch 1 is supplied to the semiconductor switch 1 via the switching signal line 14 at a time that is delayed after the time the overload disappears by a delay period which is a function of the overload and increases with it. The greater the overload, the later the switching signal for closing the semiconductor switch 1 occurs.

Another essential function of the arrangement described here is that the overload detector 12 has an integrator 15, which is set up to integrate the current on the load path 6 into a load. When the load has reached a predetermined first overload threshold, an overload signal is output to the control device 3 via the overload signal output 13 until the load has fallen below a second overload threshold. In this case, the control device 3 measures the duration of receiving the overload signal and generates a switching signal for closing the semiconductor switch 1, provided that the duration of receiving the overload signal has not exceeded a predetermined maximum duration. However, if the duration of receiving the overload signal has exceeded the predetermined maximum duration, no switching signal is generated for closing the semiconductor switch 1. In addition, the control device 3 feeds the switching signal to the semiconductor switch 1 via the switching signal line 14 for closing the semiconductor switch 1 at exactly such a time when a certain delay period has elapsed after the overload signal has disappeared. This delay period is a function of the duration of receiving the overload signal and increases with it. Thus, the longer the duration of receiving the overload signal, the greater the duration of the delay period.

If the closing of the semiconductor switch 1 has failed, the control device 3 repeatedly feeds a switching signal to the semiconductor switch 1 via the switching signal line 14 for closing it, with a time interval between the successive switching signals, which is a function of the duration of receiving the overload signal and increases with it. Thus, the longer the duration of receiving the overload signal, the greater the time interval between the successive switching signals for closing the semiconductor switch 1. However, if the semiconductor switch 1 fails to close, a maximum of a number of consecutive switching signals is supplied to the semiconductor switch 1 for closing it, which number is a function of the duration of receiving the overload signal and falls with it. The longer the duration of receiving the overload signal, the lower the number of maximum attempts to restart.

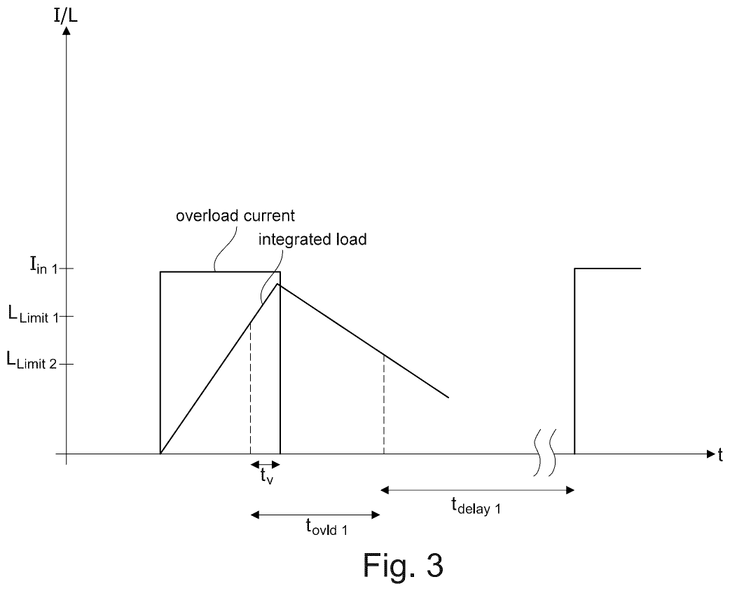

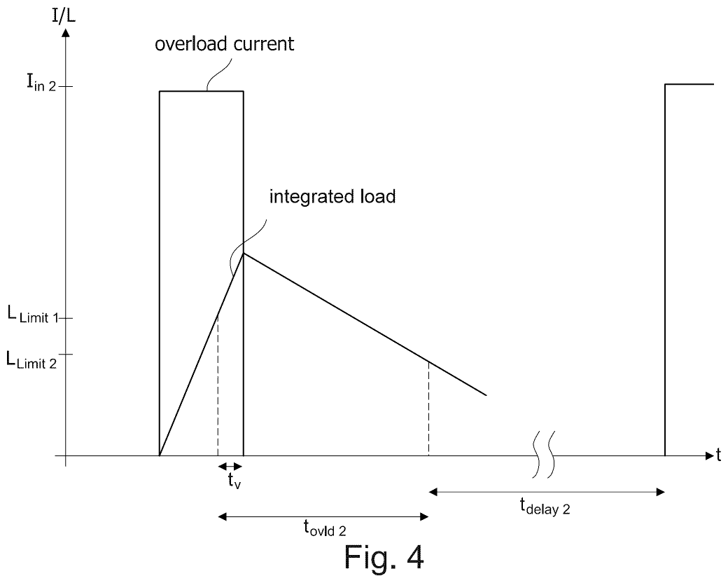

FIGS. 3 and 4 now schematically show the time behavior of a method according to the preferred exemplary embodiment at a lower or a higher overload. In the diagrams in FIGS. 3 and 4, respectively, the current I and the load L obtained by the current integrated over time are plotted with respect to the time t. If an overload current Iᵢₙ₁ occurs, as shown in FIG. 3, the load increases over time until it reaches a value L_{Limit 1}, which represents the first overload threshold at which the semiconductor switch 1 is opened. This opening of the semiconductor switch 1 occurs with a certain intrinsic time delay tᵥ, which in the present case is about 35 μs. When the semiconductor switch 1 is opened after this time delay, the load decreases again, with the overload signal remaining available until the load has fallen below the second overload threshold L_{Limit 2}. The time from reaching the first overload threshold to reaching the second overload threshold in which the overload signal was applied is designated in FIG. 3 as t_{ovld 1} and is approx. 5 to 7 ms in the example described here. However, the semiconductor switch 1 is not immediately activated for closing again if the second overload threshold has been undercut. Rather, the system waits a delay time t_{delay 1} until the semiconductor switch 1 is closed, namely with a lower overload current at the level of a double rated current, for example an overload current of approx. 30 A at a rated current of 15 A, as in the example described here, with a delay time t_{delay 1} of a maximum of 1 s, especially preferred with a delay time t_{delay 1} of approx. 600 ms.

In the example shown in FIG. 4, the overload current is significantly higher, which is about 150 A here. Therefore, the first overload threshold L_{Limit 1} is reached more quickly. As in the example described above, the semiconductor switch 1 is opened after a time delay tᵥ of about 35 μs. Even after the overload current has disappeared, the overload remains for a certain time. Overall, the overload in the present case is available for a duration t_{ovld 2}, which is significantly greater than the duration t_{ovld 1} at the previously described significantly lower overload current of approx. 30 A and in the range of 30 to 50 ms. If the overload has fallen below the second overload threshold L_{Limit 2}, no restart is attempted in this case either. Rather, a delay time t_{delay 2} is then waited until the semiconductor switch 1 is closed, which is significantly longer than the delay time t_{delay 1} in the previous example due to the greater overload here, e.g., between 750 ms and 2 s, especially preferably about 800 ms.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. An arrangement comprising:
a semiconductor switch;
a measuring circuit; and
a control device,
wherein the semiconductor switch comprises a load path input and a load path output for connection to a load path and a switching signal input for receiving a switching signal for opening or closing the semiconductor switch, the load path input and the load path output are connected to each other in a closed state of the semiconductor switch and separated from each other in an open state of the semiconductor switch,
wherein the measuring circuit comprises a load path input with which the measuring circuit is connectable to the load path, a shunt connected in series downstream of the load path input, a load path output connected in series downstream of the shunt, which is routed to the load path input of the semiconductor switch, a voltage tap for the voltage dropping across the shunt and an overload detector with an overload signal output connected in series downstream of the voltage tap, which is routed to the control device,
wherein the overload detector is set up to detect the presence of an overload on the load path and to output an overload signal to the control device via the overload signal output in an event of an overload,
wherein the control device is connected to the switching signal input of the semiconductor switch via a switching signal line,
wherein the control device is configured to supply the semiconductor switch with a switching signal for opening the semiconductor switch via the switching signal line if the control device has received an overload signal from the overload detector via the overload signal output, and
wherein the control device is configured to supply the semiconductor switch with a switching signal for closing the semiconductor switch via the switching signal line after the overload signal has disappeared, provided that the overload has not amounted to more than a predetermined maximum overload, and in a case where the overload has exceeded the predetermined maximum overload, to no longer generate a switching signal for closing the semiconductor switch even after the overload signal has disappeared.

2. The arrangement according to claim 1, wherein the control device is designed to supply to the semiconductor switch with the switching signal for closing the semiconductor switch via the switching signal line at a time, which, after the time the overload has disappeared, is delayed by such a delay period that is a function of the overload and increases with it.

3. The arrangement according to claim 2, wherein:
the overload detector has an integrator which is configured to integrate the current on the load path into a load and, in the event that the load has reached a predetermined first overload threshold, to output an overload signal to the control device via the overload signal output until the load has fallen below a second overload threshold,
the control device is set up to measure the duration of receiving the overload signal,
the control device is designed to generate a switching signal for closing the semiconductor switch provided that the duration of receiving the overload signal has not exceeded a predetermined maximum duration, and in a case where the duration of receiving the overload signal has exceeded the predetermined maximum duration, to no longer to generate a switching signal for closing the semiconductor switch, and
the control device is set up to supply the switching signal for closing the semiconductor switch to the semiconductor switch via the switching signal line at a time when, after the overload signal has disappeared, a delay period has elapsed which is a function of the duration of receiving the overload signal and increases with it.

4. The arrangement according to claim 3, wherein the control device is designed to repeatedly supply a switching signal for closing the semiconductor switch via the switching signal line to the semiconductor switch in the event the semiconductor switch has failed to close, with a time interval between the successive switching signals which is a function of the duration of receiving the overload signal and increases with it.

5. The arrangement according to claim 3, wherein the control device is set up to repeatedly supply a switching signal for closing the semiconductor switch via the switching signal line to the semiconductor switch in the event the semiconductor switch has failed to close, and at a maximum in a number that is a function of the duration of receiving the overload signal and coincides with it.

6. The arrangement according to claim 3, wherein the overload detector has a capacitor as integrator.

7. The arrangement according to claim 3, wherein a preamplifier with a signal rectifier is connected upstream of the integrator.

8. The arrangement according to claim 6, wherein the integrator is followed by a threshold comparator and subsequently a signal isolator.

9. The arrangement according to claim 1, wherein the control device has an FPGA or a microcontroller and/or the semiconductor switch is a MOSFET switch.

10. A method for switching a semiconductor switch via a measuring circuit and a control device, the measuring circuit comprising:
a load path input with which it is connected to a load path;
a shunt connected in series downstream of the load path input;
a load path output connected in series downstream of the shunt, which is routed to the semiconductor switch;
a voltage tap for a voltage dropping across the shunt, and
an overload detector connected in series downstream of the voltage tap, with an overload signal output that is routed to the control device,
the method comprising:
detecting a presence of an overload on the load path via the overload detector and, in a presence of an overload, issuing an overload signal via the overload signal output to the control device;
feeding a switching signal for opening the semiconductor switch from the control device to the semiconductor switch via the switching signal line when the control device has received an overload signal from the overload detector via the overload signal output; and
feeding a switching signal for closing the semiconductor switch from the control device to the semiconductor switch via the switching signal line after the overload signal has disappeared, provided that the overload has not exceeded a predetermined maximum overload.

11. The method according to claim 10, further comprising:
feeding the switching signal to the semiconductor switch for closing the semiconductor switch via the switching signal line at a time which, after the time the overload has disappeared, is delayed by a delay period that is a function of the overload and increases with it.

12. The method according to claim 11, further comprising:
integrating the current on the load path to a load via an integrator of the overload detector;
outputting, in the case where the load has reached a predetermined first overload threshold, an overload signal via the overload signal output to the control device until the load has fallen below a second overload threshold;
measuring the duration of receiving the overload signal via the control device;
generating a switching signal for closing the semiconductor switch via the control device, provided that the duration of receiving the overload signal has not exceeded a predetermined maximum duration; and
feeding the switching signal for closing the semiconductor switch from the control device to the semiconductor switch via the switching signal line at a time when a delay period has elapsed after the overload signal has disappeared, which is a function of a duration of receiving the overload signal and increases with it.

13. The method according to claim 12, further comprising:
repeatedly feeding a switching signal for closing the semiconductor switch from the control device to the semiconductor switch via the switching signal line in an event the semiconductor switch has failed to close, with a time interval between the successive switching signals, which is a function of the duration of receiving the overload signal and increases with it.

14. The method according to claim 12, further comprising:
repeatedly feeding a switching signal for closing the semiconductor switch from the control device to the semiconductor switch via the switching signal line in the event the semiconductor switch has failed to close, and at a maximum in a number that is a function of the duration of receiving the overload signal and falls with it.

15. The arrangement according to claim 1, wherein the arrangement is for a Failure Insertion Unit.
